(19) United States
(12) Patent Application Publication
(10) Pub. No.: US 2026/0177648 A1
(43) Pub. Date: Jun. 25, 2026

(54) DEVICE FOR INSERTING A SAMPLE-CARRIER ROTOR INTO AN NMR PROBE

(71) Applicant: COMMISSARIAT A L'ENERGIE ATOMIQUE ET AUX ENERGIES ALTERNATIVES, Paris (FR)

(72) Inventors: Eric BOULEAU, Grenoble cedex 09 (FR); Gaël DE PAËPE, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 19/127,599

(22) PCT Filed: Nov. 6, 2023
(86) PCT No.: PCT/EP2023/080828

§ 371 Date: May 6, 2025

(30) Foreign Application Priority Data
Nov. 8, 2022 (FR) FR2211621

(51) Int. Cl. G01R 33/30; G01N 24/08

(52) U.S. Cl. CPC G01R 33/307; G01N 24/08; G01R 33/305

(57) ABSTRACT

A device for inserting a sample into a sealed enclosure includes: a sample carrier for holding the sample; an insertion rod including an elongate portion for bearing the sample carrier; a transfer airlock including an outer door to close in a watertight manner and to open onto an environment outside the sealed enclosure, an inner door to close in a watertight manner and to open onto the inside of the sealed enclosure, and a sealed chamber defined between the outer door and the inner door when they are in the sealed configuration, the sealed chamber being able to accommodate the sample carrier inserted by the insertion rod; and a system for purifying the contained fluid medium, the sample carrier, and the sample which are accommodated in the sealed chamber.

### TECHNICAL FIELD

The present invention concerns devices for transferring an object from one fluid environment to another, with the two environments having different fluids and/or temperatures and/or pressures.

Although it is described for an application of spectroscopy by nuclear magnetic resonance (NMR), the present invention can be implemented in any other application which requires the sealed transfer of an object from one fluid environment to another fluid environment, more particularly with an environment with controlled pressure and/or humidity and/or particle pollution and/or at radiological level.

### PRIOR ART

Spectroscopy by nuclear magnetic resonance (NMR) is a non-destructive analysis method which uses the phenomenon of nuclear magnetic resonance (NMR), in particular to resolve the molecular structures. The NMR takes place when non-zero spin atomic nuclei are placed in a static magnetic field, and are excited by electromagnetic radiation. This method is used in particular in organic chemistry, in inorganic chemistry, in biology, and in materials science.

In solid NMR spectroscopy, the sample to be analyzed is conventionally placed in a rotor, in order to make it rotate around an axis which is inclined by 54° 44′, known as the magic angle, in relation to the static magnetic field.

It is also known that the increase of the intensity of the magnetic field, the increase of the frequency of rotation of the rotor, and/or the use of the dynamic nuclear polarization phenomenon (DNP) make it possible to improve the sensitivity and resolution of the NMR spectroscopy.

It has been proved that, during an analysis by NMR, the lower the temperature, the greater the ratio of signal to noise is, and the greater the gain caused by the DNP phenomenon is. Thus, high-resolution NMR spectrometers generally operate at a low temperature, in particular at approximately 100 K. The article by Yoh Matsuki and Toshimichi Fujiwara, «Cryogenic Platforms and Optimized DNP sensitivity», eMagRes, 2018, Vol 7:9-24, describes an NMR spectrometer which uses the DNP phenomenon, and operates at temperatures lower than 100 K.

In order to obtain low temperatures, for example of approximately 100 K or less, it is preferable for the NMR spectrometer to operate autonomously and in a closed loop. A device which operates autonomously is a device which does not need a supply of cryogenic fluid. A device in a closed loop is a device in which a work fluid circulates without exposure to the exterior environment, and without transfer of fluid outside the loop.

In autonomous devices of this type and in a closed loop, it is important to maintain great purity of the work fluid, i.e. for it to be free as far as possible from impurities irrespective of their nature (gaseous, solid in the form of particles, obtained from hydrocarbons, etc.).

For NMR spectrometers, pollution of the work fluid can be caused by putting the sample to be analyzed into place in the NMR probe.

FIGS. 1A to 1E illustrate the different steps of putting a sample into place into a probe 1 of an NMR spectrometer according to the prior art.

The probe 1 comprises a base wall 2, a cover 3 and a stator 4.

In order to be able to open the probe 1, it is firstly necessary to heat the internal environment 5 delimited by the base wall 2 and the cover 3 assembled to one another in a sealed manner (FIG. 1A).

The probe 1 is then opened manually by raising the sealed cover 3 (FIG. 1B).

Then, a rotor 6 in which a sample to be analyzed is accommodated, is put into place manually in the stator 4 (FIG. 1C).

The cover 3 is then put back into place in order to close the probe 1 once more in a sealed manner (FIG. 1D).

The internal environment 5 is then cooled, then a series of purification cycles of the work fluid is applied, in order to remove the impurities introduced during the opening of the probe 1 and the insertion of the rotor 6 into the stator 4 (FIG. 1E).

The total duration of the steps described, relating to the putting into place of a sample in the probe 1, is approximately eight hours, which is particularly time-consuming. In addition, the purification cycles are complex to implement.

There is therefore a need for a solution which makes it possible to reduce the duration of putting a sample to be analyzed into place in an NMR probe, and to simplify the implementation of the existing process.

More generally, there is a need for a solution which makes it possible to transfer a sample simply and rapidly from an exterior environment to a controlled environment, while limiting the introduction of impurities into the controlled environment.

The objective of the invention is to fulfil this need/these needs at least partly.

### SUMMARY OF THE INVENTION

For this purpose, the invention concerns a device for inserting a sample into a hermetic enclosure, the device comprising:
a sample-carrier to carry the sample;
an insertion rod comprising an elongate portion, an end of which is designed to carry the sample-carrier;
a transfer airlock comprising:
   an outer door, which is designed to be closed in a sealed manner, and open onto an environment on the exterior of the hermetic enclosure;
   an inner door, which is designed to be closed in a sealed manner, and open onto the interior of the hermetic enclosure, directly or indirectly by means of at least one sealed duct;
   a sealed chamber delimited between the outer door and the inner door, when they are in the configuration closed in a sealed manner, with the sealed chamber being configured to accommodate the sample-carrier, inserted by the insertion rod;
a system for purification of the fluid environment contained, and of the sample-carrier and the sample accommodated in the sealed chamber.

The purification system according to the invention serves the purpose of decreasing the level of impurities and/or the level of radioactivity of the fluid environment contained in the sealed chamber, and consequently of the sample-carrier and the sample to be analyzed which it carries.

“Level of impurities of a fluid environment” means here and within the context of the present invention, the ratio, expressed generally in ppm (parts/million) of the mass fraction of the impurities contained in the fluid environment, to the total mass of said fluid environment.

The radioactive elements and/or the impurities are all gaseous, liquid, or solid elements in the form of particles which are not desirable in the target fluid environment, i.e. which do not correspond to the level of purity and/or the level of radioactivity of the fluid which is required to fill a hermetic enclosure. For example, the level of impurities can be 100 ppm or less.

Preferably, the outer door comprises a gland which is configured to be compressed in a sealed manner by the elongate portion of the insertion rod, while leaving it movable in translation.

Preferably, the purification system comprises:
a discharge valve, which is configured to discharge the fluid contained in the chamber down to a nominal pressure, known as low pressure;
a filling valve, which is configured to fill the chamber with a predetermined fluid, intended to fill the hermetic enclosure, up to another nominal pressure, known as high pressure.

Preferably, the low pressure is 10 mbar or less, and/or the high pressure is 1 bar or more, or 1.1 bar, preferably between 1 and 3 bars.

Preferably, the filling valve is configured such as to close passively when the pressure of the chamber reaches the high pressure.

Preferably, the predetermined fluid is a pure gas, preferably helium which is pure to at least 99.999%.

Preferably, the elongate portion extends along a length of between 15 cm and 30 cm. Preferably, the elongate portion has a cylindrical form, preferably with a diameter of between 0.3 cm and 1.0 cm.

Preferably, the end of the elongate portion, opposite that which carries the sample-carrier, comprises a grasping handle. Preferably, the grasping handle has a diameter larger than the diameter of opening of the outer door, for example 10 mm or more.

Preferably, the sample-carrier comprises a cavity in which the sample is intended to be inserted. Preferably, the cavity has a cylindrical form, preferably with a diameter of between 0.8 mm and 3.3 mm and/or a height of between 12 mm and 20 mm, for example 18 mm.

Preferably, the sample-carrier comprises a slot which opens into the cavity, and is configured to permit the injection of a fluid into the cavity, such as to propel the sample out of the cavity.

Preferably, the inner door is a slide valve, configured to slide between a closed position, in which the inner door is closed in a sealed manner, and an open position, in which the inner door is open, in order to permit the passage of the sample-carrier and the elongate portion of the insertion rod.

Preferably, the inner door is configured such as to maintain its closure sealed for a pressure of 1.10⁻⁵ mbar or less.

Preferably, the gland comprises at least one, and preferably at least two seals, clamping rings and a screw, the clamping rings being configured to compress the seal(s) when the screw is screwed, such that the seal(s) compress(es) the elongate portion, which ensures the sealing of the closure of the outer door.

Preferably, the screw is hollow, and has an inner diameter larger than the diameter of the sample-carrier and the elongate portion.

Preferably, the gland comprises an annular chamber in which the seal(s) is/are partly accommodated, with the annular chamber being at a pressure of 1.10⁻³ mbar or less.

Preferably, the chamber has a volume of between 3000 mm³ and 7000 mm³.

Preferably, the chamber has a tubular form, with the inner door at one of the ends of the tube, and the outer door at the other one of the ends of the tube.

Preferably, the distance between the outer door and the inner door is between 0 and 20 cm.

The invention also concerns a system comprising a hermetic enclosure and a device according to the invention, with the outer door of the transfer airlock being designed to open onto the environment on the exterior of the hermetic enclosure, and the inner door of the transfer airlock being designed to open directly or indirectly, via a sealed duct, into the interior of the hermetic enclosure.

Preferably, the system is a nuclear magnetic resonance (NMR) spectrometer, and the hermetic enclosure is a probe which is configured to excite the atomic nuclei of a sample.

Preferably, the probe is configured such as to implement the phenomenon of dynamic nuclear polarization.

Preferably, the internal environment of the probe is composed of a fluid in which the sample is intended to be immersed, the probe being configured to maintain said fluid at a temperature lower than 100 K, preferably said fluid being helium which is pure to at least 99.999%.

Preferably, the system comprises a rotor on which the sample is intended to be fitted, and is configured to be carried by the sample-carrier, with the probe comprising a stator configured to rotate the rotor.

Preferably, the probe comprises a pneumatic tube which connects the transfer airlock to the stator, and is configured such as to displace the rotor of the sample-carrier by propulsion when it is inserted in the probe, as far as the stator, and conversely.

The invention also concerns a method for operation of a system according to the invention, comprising the following successive steps:
a) putting a sample into place on the sample-carrier of the insertion rod;
b) insertion of the sample-carrier and the sample in the chamber of the transfer airlock through the outer door, with the inner door being closed in a sealed manner;
c) clamping of the gland in order to compress the elongate portion, such as to close the outer door in a sealed manner;
d) purification, by the purification system, of the fluid contained in the chamber;
e) opening of the inner door, and insertion of the sample-carrier and the sample in the hermetic enclosure through the inner door, with the gland being maintained clamped in order to be compressed around the elongate portion, such as to maintain the outer door closed in a sealed manner.

According to the present invention, “purification” of a fluid means reducing its level of impurities.

Preferably, the purification system of the device comprises:
a discharge valve, which is configured to discharge the fluid contained in the chamber down to a nominal pressure, known as low pressure;
a filling valve, which is configured to fill the chamber with a predetermined fluid intended to fill the hermetic enclosure, up to another nominal pressure, known as high pressure; and the step d) comprises at least one iteration of the following sub-steps:
d₁) opening of the discharge valve so as to discharge the fluid contained in the chamber, for example gas, down to a nominal pressure, known as low pressure, with the filling valve being closed;
d₂) closure of the discharge valve;
d₃) opening of the filling valve, so as to fill the chamber with the fluid which constitutes the internal environment of the hermetic enclosure, for example helium which is pure to at least 99.999%, up to another nominal pressure, known as high pressure;
d₄) closure of the filling valve.

Preferably, the low pressure is 10 mbar or less and/or the high-pressure is between 1 and 3 bars.

Preferably, the step d) comprises at least three iterations of the sub-steps d₁) to d₄).

Preferably, the system is a nuclear magnetic resonance (NMR) spectrometer, and the hermetic enclosure is a probe which is configured to excite the atomic nuclei of a sample, and, the method comprises, after the step e), a step g) of nuclear magnetic resonance spectrometry of the sample.

Preferably, the probe of the system comprises a pneumatic tube which connects the transfer airlock to the stator, and is configured such as to displace the rotor of the sample-carrier by propulsion when it is inserted in the probe, as far as the stator, and conversely, and the step g) is preceded by a step f) of putting into place the rotor, on which the sample is fitted, in the stator, by a proportion of said rotor in the pneumatic tube.

Preferably, the method comprises a subsequent step h), during which the sample is extracted from the hermetic enclosure, said step h) comprising the following successive sub-steps:
h₁) drawing of the insertion rod, such as to put the sample-carrier and the sample into place in the chamber of the transfer airlock, the sample being carried by the sample-carrier, the gland being maintained clamped in order to compress the elongate portion, such as to maintain the outer door closed in a sealed manner;
h₂) sealed closure of the inner door;
h₃) optionally, opening of the filling valve;
h₄) release of the gland, so as to open the outer door sufficiently to allow the sample-carrier and the sample to pass;
h₅) extraction of the sample-carrier and the sample from the transfer airlock through the outer door;
h₆) optionally, putting the sample-carrier back into place in the chamber of the transfer airlock, with the sample being removed from the sample-carrier, then clamping of the gland in order to compress the elongate portion such as to close the outer door in a sealed manner, if applicable with closure of the filling valve.

The present invention thus consists substantially of a device comprising a transfer airlock and an insertion rod with a sample-carrier in order to insert easily a biological sample or a sample of material to be analyzed into a hermetic enclosure, such as an NMR probe.

When the sample-carrier which carries the sample is accommodated in the chamber of the transfer airlock delimited by two doors closed in a sealed manner, the purification system can purify the impurities introduced into the chamber by the sample-carrier inserted therein.

Once the level of impurities and/or the level of radioactivity of the fluid environment contained in the chamber has reached a level sufficiently low for the hermetic enclosure, the inner door of the airlock can be opened, and the sample-carrier with the sample can be inserted by the rod in the hermetic enclosure without polluting it.

The handling for the insertion of the sample in the hermetic enclosure is easy: simple translation of the insertion rod is sufficient. According to an advantageous embodiment, the elongate portion of the rod is compressed by a gland, while leaving it movable in translation, which ensures the sealed closure of the outer door throughout the translation course of the insertion rod.

The present invention advantageously permits the transfer of a sample from an exterior fluid environment to a fluid environment contained in a hermetic enclosure, the transfer being simple and rapid to implement, while limiting the introduction of impurities into the fluid environment of the hermetic enclosure. In particular, the sample can be transferred in a few minutes. For example, for an NMR spectrometer, putting into place of a rotor, in which a sample is fitted, in a stator of the probe of the NMR spectrometer, can be carried out in five minutes thanks to the present invention, compared with eight hours for an NMR spectrometer according to the prior art.

In addition, the purification system can also be configured to set the fluid environment contained in the sealed chamber to a given pressure. This advantageously allows the insertion of the sample in the hermetic enclosure not to affect, or to affect very little, the pressure of the fluid environment of the hermetic enclosure.

### BRIEF DESCRIPTION OF THE DRAWINGS

Other advantages and characteristics will become more apparent from reading the detailed description, provided by way of non-limiting illustration, with reference to the following figures:

FIG. 1A is a schematic view of a probe according to the prior art, the cover of the probe being closed;

FIG. 1B is a schematic view of the probe according to FIG. 1A, the cover of the probe being open;

FIG. 1C is a schematic view of the probe according to FIG. 1A, the cover of the probe being open, and a rotor, on which a sample is fitted, is installed in the stator of the probe;

FIGS. 1D and 1E are schematic views of the probe according to FIG. 1A, the cover of the probe being closed, and a rotor, on which a sample is fitted, is installed in the stator of the probe;

FIG. 2A is a view from the side of an insertion rod of a device according to the invention, and a rotor on which a sample is fitted, the rotor not being inserted in the insertion rod;

FIG. 2B is a view from the side of an insertion rod of a device according to the invention, and a rotor on which a sample is fitted, the rotor being inserted in the insertion rod;

FIG. 3 is a schematic view in longitudinal cross-section of part of an NMR spectrometer comprising an airlock for transfer of a device according to the invention, connected to a probe for NMR spectrometry;

FIG. 4 is a schematic view in longitudinal cross-section of part of an NMR spectrometer comprising a device according to the invention, the transfer airlock of the device being connected to a probe for NMR spectrometry, and the insertion rod of the device being inserted partly in the transfer airlock, with the sample-carrier accommodated in the chamber of said airlock;

FIG. 5 is a schematic view in longitudinal cross-section of an NMR spectrometer comprising a device according to the invention, the transfer airlock of the device being connected to a probe for NMR spectrometry, and the sample-carrier of the insertion rod of the device being inserted in the probe;

FIG. 6 is a schematic view in longitudinal cross-section of part of an NMR spectrometer comprising a device according to the invention, the transfer airlock of the device being connected to a probe for NMR spectrometry, the sample-carrier of the insertion rod of the device being inserted in the probe, and a rotor being propelled out of the sample-carrier;

FIG. 7A is a schematic view of a probe of an NMR spectrometer connected to an airlock for transfer of a device according to the invention, the probe comprising a pneumatic tube in which a rotor is propelled towards the stator of the probe;

FIG. 7B is a schematic view of the probe and of the transfer airlock according to FIG. 7A, the rotor being inserted in the stator of the probe.

### DETAILED DESCRIPTION

For reasons of clarity, the different elements of the figures are represented in free scale, with the real dimensions of the different parts not necessarily being respected.

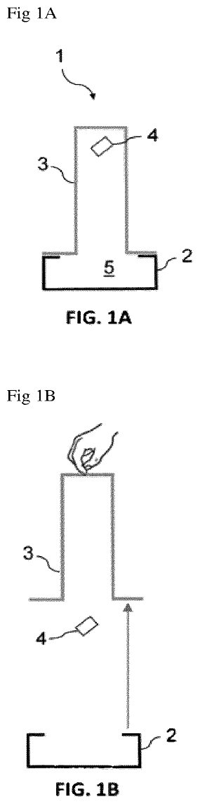

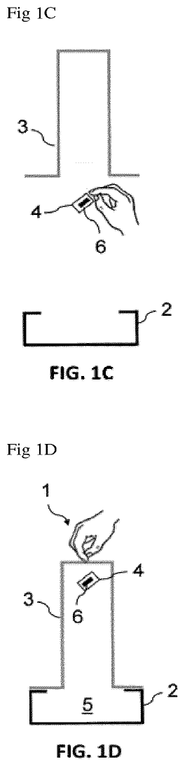

Les FIGS. 1A to 1E have already been commented on in the preamble, and will not be commented on further hereinafter.

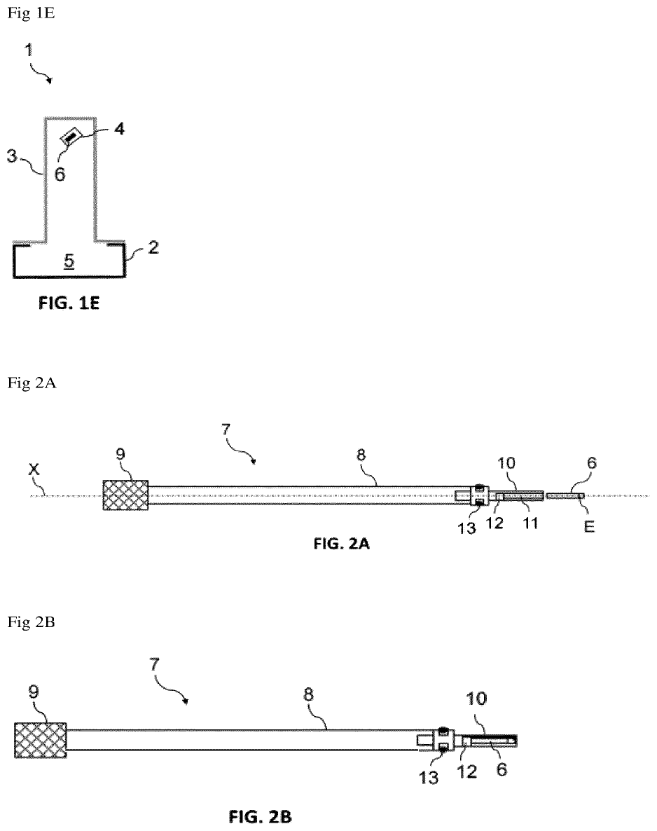

FIG. 2A illustrates the part of the insertion rod 7 of a device according to the invention, an end of which carries a rotor 6 which is intended to accommodate a sample E to be analyzed.

The insertion rod 7 comprises an elongate portion 8, extending along a longitudinal axis X, one of the longitudinal ends of which is in the form of a grasping handle 9, and the other one of the longitudinal ends of which can carry a sample-carrier 10. The elongate portion 8 can be a cylinder with a length of 180 mm, with a diameter of 6 mm. The handle 9 can be cylindrical, for example with a length of 20 mm, and can comprise striations in order to facilitate the grasping of the insertion rod 7.

The sample-carrier 10 comprises a cavity 11 to accommodate and support the rotor 6, and a slot 12 which opens into the cavity 11, between the longitudinal end of the elongate portion 8 and the cavity 11. The cavity 11 has a cylindrical form with a diameter of between 0.8 and 3.3 mm, for example equal to 3.3 mm, and/or a height of between 12 and 20 mm, for example equal to 18 mm. These dimensions are suitable for low-temperature NMR spectroscopy. The cavity 11 can thus have a form complementary to that of the rotor 6, which is for example a cylinder with a diameter of between 0.7 and 3.2 mm, for example equal to 3.2 mm, and/or a height of between 12 and 20 mm, for example equal to 17 mm.

The end of the elongate portion 8 and/or the sample-carrier 10 can support an O-ring seal 13 on its periphery.

In FIG. 2B, the rotor 6 is accommodated in the cavity 11.

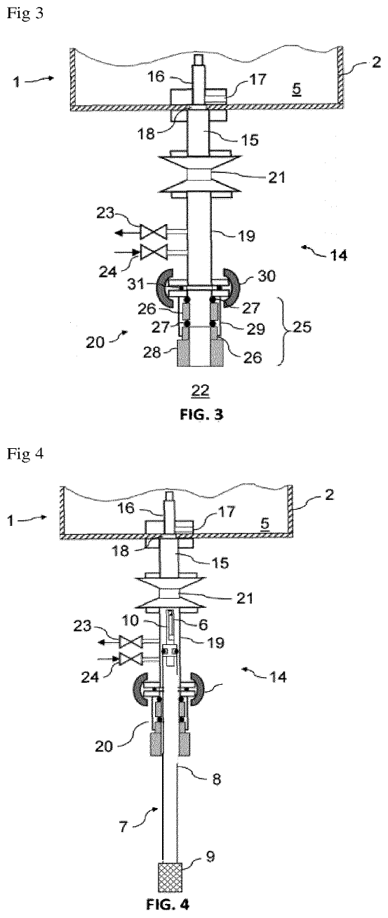

FIG. 3 illustrates an NMR spectrometer comprising an airlock 14 for transfer of a device according to the invention, assembled with a probe 1 for NMR spectrometry, by means of a sealed duct 15.

The probe 1 is a hermetic enclosure comprising a sealed wall 2, the internal environment 5 of which is composed of helium, which is pure to at least 99.999%.

The probe 1 differs from that of the prior art illustrated in FIGS. 1 to 1D, in particular in that it comprises a pneumatic tube 16 arranged in the hermetic enclosure, and a connection 17 which opens into the interior of the pneumatic tube 16, such as to be able to inject gas, preferably helium, which is pure to at least 99.999%, into the pneumatic tube 16. A passage 18 connects the sealed duct 15 in a sealed manner to the pneumatic tube 16.

The transfer airlock 14 comprises a chamber 19 which is delimited by an outer door 20 and an inner door 21, when they are in their sealed closed configuration. The outer door can open onto an environment M on the exterior of the hermetic enclosure, and the inner door 21 can open onto the sealed duct 15. The distance between the outer door 20 and the inner door 21 is less than the length of the elongate portion 8.

In the example illustrated, the chamber 19 has a hollow cylindrical form, preferably with a diameter of 45 mm or less.

The inner door 21 is a slide valve which can be closed in a sealed manner, and can be opened sufficiently to permit the passage of the sample-carrier 10 and the elongate portion 8.

The outer door 20 comprises a gland 25 which is configured to compress the elongate portion 8 in a sealed manner, while leaving the insertion rod 7 movable in translation in order to be inserted in the transfer airlock 14.

The gland 25 comprises two clamping rings 26, two seals 27 and a hollow screw 28. The inner diameter of the hollow screw 28, which is smaller than the diameter of the handle 9, is sufficient to permit the passage of the sample-carrier 10 with the sample E and of the elongate portion 8. When the hollow screw 28 is screwed, it compresses the clamping rings 26 against the seals 27, which are then compressed. The compression of the seals 27 reduces their inner diameter, which can thus be smaller than the outer diameter of the elongate portion 8. Thus, the seals 27 which surround the elongate portion 8 while being compressed, are compressed around the elongate portion 8, which provides the sealed closure of the outer door 20.

The gland 25 also comprises an annular chamber 29 around the clamping rings 26 and the seals 27. The annular chamber 29 is pumped under vacuum to a pressure, typically of 1.10⁻³ mbar or less. Thus, the volume between the clamping rings 26 and the seals 27, and the volume between the two seals 27, is at a pressure of 1.10⁻³ mbar or less, which makes it possible to guarantee better compression of the seals, and better sealing of the closure of the outer door.

The outer door 20 also comprises a clamping flange 30 which compresses a seal 31, in order to guarantee the sealing between the gland 25 and the interior of the chamber 19.

The chamber 19 is configured to accommodate the sample-carrier 10 with the elongate portion 8 compressed by the gland 25, with the chamber 19 thus being closed in a sealed manner. The chamber 19 is also configured to have the sample-carrier 10 passing through it, through the outer door 20 and the inner door 21.

The transfer airlock 14 also comprises a discharge valve 23, which is configured to discharge the fluid contained in the chamber 19, and a filling valve 24, that is configured to fill the chamber 19 with helium, which is pure to at least 99.999%. Thus, the purification fluid can be the same fluid as that of the inner environment 5.

The method for insertion of a sample E into the probe 1 with the device according to the invention will now be described.

Firstly, the method comprises a step a) of putting the sample E into place on the insertion rod 7. During this step a), the sample E is fitted in the rotor 6, then, the rotor 6 is inserted in the cavity 11 of the sample-carrier 10, as illustrated in FIG. 2B.

The method then comprises a step b) of insertion of the rotor 6 and the sample-carrier 10 in the chamber 19. During this step b), the inner door 21 is closed in a sealed manner, and the valves 23 and 24 are also closed in a sealed manner. The insertion is carried out by translation of the insertion rod 7 through the outer door 20, with the gland 25 not being clamped. After insertion, the gland 25 is arranged without compression around the elongate portion 8, and the rotor 6 and the sample-carrier 10 are entirely accommodated in the chamber 19 (FIG. 4).

The step b) is followed by a step c) during which the gland 25 is clamped, such as to be compressed around the elongate portion 8, and thus close the outer door 20 in a sealed manner. The chamber 19 is thus closed hermetically with the rotor 6 and the sample-carrier 10 accommodated in the interior.

A step d) is then carried out of purification of the fluid contained in the chamber 19. This step d) comprises at least one iteration of the following sub-steps:
d₁) opening of the discharge valve 23, such as to discharge the fluid contained in the chamber, for example gas, to a nominal pressure, known as low pressure, with the filling valve 24 being closed;
d₂) closure of the discharge valve 23;
d₃) opening of the filling valve 24, such as to fill the chamber 19 with the fluid which constitutes the inner environment 5 of the probe 1, up to another nominal pressure, known as high pressure;
d₄) closure of the filling valve 24, with the closure being able to be carried out passively when the pressure inside the chamber 19 reaches the high pressure.

This step d) of purification makes it possible to remove the impurities imported during the insertion of the rotor 6 and the sample-carrier 10 into the chamber 19 by dilution. In particular, during the step b), the chamber 19 is filled with the atmosphere of the exterior environment M. The step d) then makes it possible to dilute the pollutant gases with fluid which constitutes the interior environment 5, sufficiently for the level of impurities contained in the chamber 19 after purification to be 0.00001% or less, corresponding to 100 ppm.

The step d) can comprise at least three iterations of the sub-steps d₁) to d₄). The ratio of the volume of the chamber 19 to the volume of the hermetic enclosure 1 can be 1/100000 or less. This advantageously makes it possible to increase the dilution of the pollutants at each iteration of the sub-steps d₁) to d₄) and, consequently, to increase the speed at which the level of impurities of the fluid environment of the chamber 19 decreases. The level of dilution of the impurities at each iteration of the sub-steps d₁) to d₄), i.e. the ratio between the level of impurities after an iteration and the level of impurities before said iteration, can in particular be 1% or less, or 0.9% or less.

The step d) is followed by a step e), during which the inner door 21 opens and the insertion rod 7 slides along its elongate portion 8 as far as insertion of the rotor 6 and the sample-carrier 10 into the pneumatic tube 16. The gland 25 is maintained clamped during all of the step e), such as to maintain the outer door 20 closed in a sealed manner. The clamping during the step e) can be lower than during the step d), so as to facilitate the movement in translation of the insertion rod 7. In particular during the step d), the clamping of the gland 25 can be such that it blocks any translation of the insertion rod 7, and thus maintains the rotor 6 and the sample-carrier 10 in a fixed position in the chamber 19. During the step e), the gland 25 can be slightly released, such as to maintain the outer door 20 closed in a sealed manner, and to permit the translation of the insertion rod 7 along the longitudinal axis X.

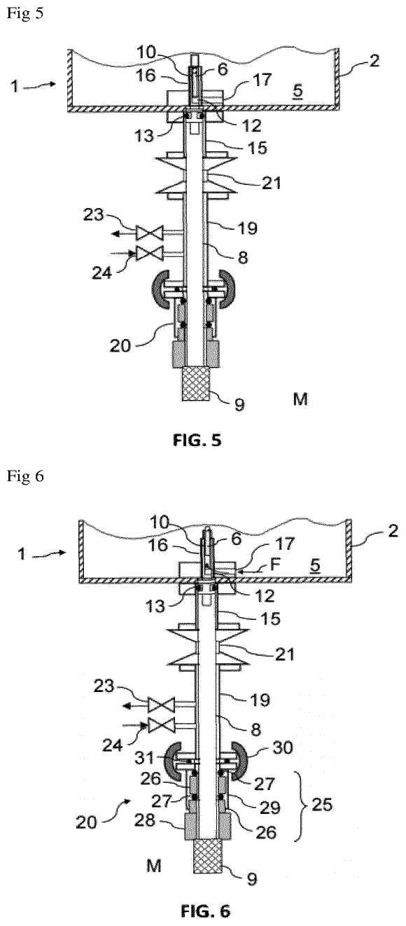

FIG. 5 illustrates the NMR spectrometer with the rotor 6 and the sample-carrier 10 inserted in the pneumatic tube 16 of the probe 1 by means of the rod of the device according to the invention. In this configuration, the handle 9 abuts the outer door 20. The O-ring seal 13 is accommodated in the passage 18, such as to guarantee the sealing between the sealed duct 15 and the pneumatic tube 16. The slot 12 is aligned with the connection 17.

The step e) is followed by a step f) of putting into place the rotor 6, on which the sample E is fitted, in the stator 4 of the probe 1. In particular, the step f) is carried out by propulsion of the rotor 6 in the pneumatic tube 16. As illustrated in FIG. 6, a fluid F, which is preferably helium pure to within 99.999%, circulates in the connection 17 as far as in the cavity 11, by means of the slot 12. Under the thrust of the fluid F, the rotor 6 is propelled out of the cavity 11, and guided along the pneumatic tube 16.

During the guiding in the pneumatic tube 16 and in the NMR probe, the insertion rod 7 is maintained inserted in the transfer airlock 14 with the outer door 20 closed in a sealed manner.

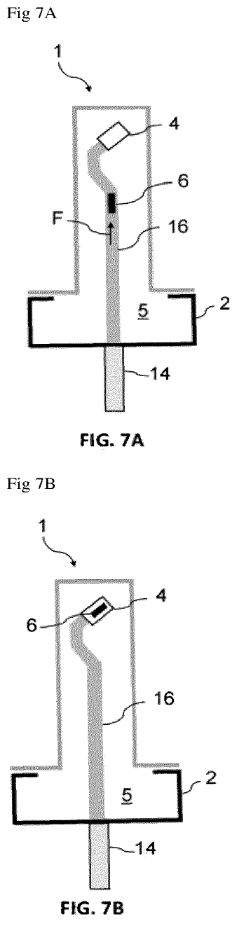

FIG. 7A illustrates the guiding, along the pneumatic tube 16, of the rotor 6 propelled by the fluid F as far as the stator 4 of the probe 1.

FIG. 7B illustrates the rotor 6 introduced into the stator 4 of the probe 1. During a step g), the sample E will then be observed by NMR spectrometry. During the step g), the rotor 6 rotates the sample E in the stator 4 around an axis which is inclined by 54° in relation to the magnetic field for the NMR spectrometry. The speed of rotation of the sample E can be greater than one or more millions of revolutions per minute. The stator 4 can comprise an aerostatic bearing, which is supplied with helium pure to at least 99.999%, in order to guide the rotor 6 in rotation. The sample E can be rotated by a flow of helium, which is pure to at least 99.999%.

Preferably, during the step g), the interior environment 5 of the probe 1 is at a pressure of between 1 and 3 bars, and/or at a temperature of 100 K or less. In particular, the probe 1 can operate autonomously and in a closed loop, for example it can comprise heat exchangers and at least one cold source, for example cryo-refrigerators. Since the interior environment 5 is composed of helium, which is pure to at least 99.999%, control of the interior environment 5 at the aforementioned pressure and temperature is facilitated. The stator 4 can be supplied with helium, which is pure to at least 99.999% and at a temperature lower than 100 K, with the flow of this cold helium making it possible to maintain the sample E at a temperature lower than 100 K.

After the NMR spectrometry, the rotor 6 and the sample E can be extracted from the probe 1 during a step h). For this purpose, the step h) comprises a sub-step h₁) during which the rotor 6, on which the sample E is fitted, will be propelled out of the stator 4 and guided along the pneumatic tube 16 until it is inserted in the cavity 11 of the sample-carrier 10. Then, the insertion rod 7 is drawn such as to put the sample-carrier 10 and the sample E into place in the chamber 19 of the transfer airlock 14, with the outer door 20 being maintained closed in a sealed manner by the elongate portion 8 and the gland 25.

The sub-step h₁) is followed by a sub-step h₂) during which the inner door 21 is closed in a sealed manner. This is followed by a sub-step h₃) of opening of the filling valve 24, and helium pure to at least 99.999% then fills the chamber 19.

Next, the gland 25 is released during a sub-step h₄), such that the outer door 20 permits the passage of the sample-carrier 10 and the sample E. Then, the insertion rod 7 is drawn towards the exterior, during a sub-step h₅), in order to extract the sample-carrier 10 and the sample E from the transfer airlock 14 through the outer door 20.

The step h) comprises a further sub-step h₆), during which the sample E is extracted from the cavity of the sample-carrier 10, then the sample-carrier 10 is put back into place in the chamber 19 without the sample E. The gland 25 is then clamped such as to compress the elongate portion 8 and close the outer door 20 in a sealed manner. Then, the filling valve 24 is closed in a sealed manner.

Other variants and improvements can be envisaged, without departing from the context of the invention as defined by the following claims.

In particular, although described as an application for NMR spectroscopy, the present invention can be applied to any system which requires the transfer of an object from a fluid environment to another fluid environment, in particular a controlled environment.

1-16. (canceled)

17. A device for inserting a sample into a hermetic enclosure, the device comprising:
a sample-carrier to carry the sample;
an insertion rod comprising an elongate portion, an end of which is configured to carry the sample-carrier;
a transfer airlock comprising:
an outer door configured to be closed in a sealed manner and open onto an environment on an exterior of the hermetic enclosure;
an inner door configured to be closed in a sealed manner and open onto an interior of the hermetic enclosure, directly or indirectly via at least one sealed duct; and
a sealed chamber delimited between the outer door and the inner door, when they are in the configuration closed in a sealed manner, with the sealed chamber being configured to accommodate the sample-carrier, inserted by the insertion rod; and
a system for purification of a fluid environment contained, and of the sample-carrier and the sample accommodated in the sealed chamber.

18. The device as claimed in claim 17, wherein the outer door comprises a gland which is configured to be compressed in a sealed manner by the elongate portion of the insertion rod, while leaving it movable in translation.

19. The device as claimed in claim 17, wherein the purification system comprises:
a discharge valve configured to discharge a fluid contained in the sealed chamber down to a nominal pressure, known as low pressure; and
a filling valve configured to fill the sealed chamber with a predetermined fluid, configured to fill the hermetic enclosure, up to another nominal pressure, known as high pressure.

20. The device as claimed in claim 17, wherein the sample-carrier comprises a cavity in which the sample is configured to be inserted.

21. The device as claimed in claim 20, wherein the sample-carrier comprises a slot which opens into the cavity and is configured to permit an injection of a fluid into the cavity, to propel the sample out of the cavity.

22. The device as claimed in claim 17, wherein the inner door is a slide valve configured to slide between a closed position in which the inner door is closed in a sealed manner and an open position in which the inner door is open in order to permit passage of the sample-carrier and the elongate portion of the insertion rod.

23. The device as claimed in claim 17, wherein the inner door is configured to maintain its closure sealed for a pressure of 1.10⁻⁵ mbar or less.

24. The device as claimed in claim 18, wherein the gland comprises at least one seal, clamping rings, and a screw,
the clamping rings being configured to compress the at least one seal when the screw is screwed, such that the at least one seal compresses the elongate portion, which ensures a sealing of the closure of the outer door.

25. The device as claimed in claim 18, wherein the gland comprises at least two seals, clamping rings, and a screw,
the clamping rings being configured to compress the at least two seals when the screw is screwed, such that the at least two seals compress the elongate portion, which ensures a sealing of the closure of the outer door.

26. A system comprising:
the hermetic enclosure; and
the device as claimed in claim 17,
wherein with the outer door of the transfer airlock is configured to open onto the environment on the exterior of the hermetic enclosure, and the inner door of the transfer airlock is configured to open directly or indirectly, via the sealed duct, into the interior of the hermetic enclosure.

27. The system as claimed in claim 26, wherein the system is a nuclear magnetic resonance spectrometer, and the hermetic enclosure is a probe which is configured to excite atomic nuclei of a sample, the probe being configured to implement a phenomenon of dynamic nuclear polarization.

28. The system as claimed in claim 27, further comprising a rotor on which the sample is configured to be fitted and configured to be carried by the sample-carrier with the probe comprising a stator configured to rotate the rotor.

29. The system as claimed in claim 28, wherein the probe comprises a pneumatic tube which connects the transfer airlock to the stator and is configured to displace the rotor of the sample-carrier by propulsion when it is inserted in the probe, as far as the stator, and conversely.

30. A method for operating the system as claimed in claim 26, comprising the following successive steps:
a) putting the sample into place on the sample-carrier of the insertion rod;
b) inserting the sample-carrier and the sample in the sealed chamber of the transfer airlock through the outer door, with the inner door being closed in a sealed manner;
c) clamping of a gland in order to compress the elongate portion to close the outer door in a sealed manner;
d) purifying, by the purification system, a fluid contained in the sealed chamber;
e) opening of the inner door, and inserting the sample-carrier and the sample in the hermetic enclosure through the inner door, with the gland being maintained clamped in order to be compressed around the elongate portion, to maintain the outer door closed in a sealed manner.

31. The method as claimed in claim 30, wherein the purification system comprises a discharge valve configured to discharge the fluid contained in the sealed chamber down to a nominal pressure, known as low pressure and a filling valve configured to fill the sealed chamber with a predetermined fluid, configured to fill the hermetic enclosure, up to another nominal pressure, known as high pressure
the step d) comprising at least one iteration of the following sub-steps:
d₁) opening the discharge valve so as to discharge the fluid contained in the sealed chamber down to the low pressure with the filling valve being closed;
d₂) closing the discharge valve;
d₃) opening the filling valve so as to fill the sealed chamber with the fluid which constitutes the interior of the hermetic enclosure which is pure to at least 99.999%, up to the high pressure;
d₄) closing the filling valve.

32. The method as claimed in claim 31, wherein the fluid in sub-step d₁) is gas and the fluid in sub-step d₃) is helium.

33. The method as claimed in claim 31, wherein the system is a nuclear magnetic resonance spectrometer, and the hermetic enclosure is a probe which is configured to excite atomic nuclei of a sample, the probe being configured to implement a phenomenon of dynamic nuclear polarization,
wherein the method further comprises, after the step e), a step g) of nuclear magnetic resonance spectrometry of the sample.

34. The method as claimed in claim 33, further comprising a subsequent step h), during which the sample is extracted from the hermetic enclosure, said step h) comprising the following successive sub-steps:
h₁) drawing the insertion rod to put the sample-carrier and the sample into place in the sealed chamber of the transfer airlock, the sample being carried by the sample-carrier, the gland being maintained clamped in order to compress the elongate portion, to maintain the outer door closed in a sealed manner;
h₂) sealing closure of the inner door;
h₃) opening the filling valve;
h₄) releasing the gland so as to open the outer door sufficiently to allow the sample-carrier and the sample to pass;
h₅) extracting the sample-carrier and the sample from the transfer airlock through the outer door.

35. The method as claimed in claim 34, wherein said step h) further comprises the following sub-step after sub-step h₅):
h₆) putting the sample-carrier back into place in the sealed chamber of the transfer airlock, with the sample being removed from the sample-carrier, then clamping of the gland in order to compress the elongate portion to close the outer door in a sealed manner, when applicable with closure of the filling valve.
